(19) United States
(12) Patent Application Publication
(10) Pub. No.: US 2023/0041756 A1
(43) Pub. Date: Feb. 9, 2023

(54) SIGNAL PROCESSING CIRCUIT

(71) Applicant: Egis Technology Inc., Hsinchu County (TW)

(72) Inventors: Chung-Yi Wang, Hsinchu County (TW); Yu-Hsuan Lin, Hsinchu County (TW); Tzu-Li Hung, Hsinchu County (TW)

(73) Assignee: Egis Technology Inc., Hsinchu City (TW)

(21) Appl. No.: 17/792,395

(22) PCT Filed: Aug. 12, 2020
(86) PCT No.: PCT/CN2020/108664

§ 371 Date: Jul. 12, 2022

Related U.S. Application Data
(60) Provisional application No. 62/960,153, filed on Jan. 13, 2020.

(51) Int. Cl. H03K 19/0175; H03K 17/56

(52) U.S. Cl. CPC H03K 19/017509; H03K 17/56

(57) ABSTRACT

A signal processing circuit includes a buffer, a first capacitor, a second capacitor, a first switch and a second switch. The buffer includes an input terminal for receiving an external signal and an output terminal for outputting an output signal. The first switch is coupled between the output terminal of the buffer and the first capacitor. The second switch is coupled between the output terminal of the buffer and the second capacitor. The first switch and the second switch are turned on alternately.

### CROSS REFERENCE TO RELATED APPLICATIONS

This application claims priority to U.S. Provisional Application No. 62/960,153, filed on Jan. 13, 2020, and incorporated herein by reference in its entirety.

### BACKGROUND OF THE INVENTION

### 1. Field of the Invention

The disclosure is related to a signal processing circuit, and more particularly, a signal processing circuit capable of sampling data through a plurality of path units.

### 2. Description of the Prior Art

In the signal processing applications related to the panel, the signals obtained from the panel side can be sampled and transmitted to the integrated circuit (IC) side to be processed. For example, a buffer can be embedded at the panel side to transmit the captured signal to a sampling switch at the IC side. When the sampling switch is turned on, the signal can be transmitted to the sampling capacitor. Then, when the sampling switch is turned off, the sampled signal can be sent to the back-end circuit for analysis and processing.

Although the above structure is usable, since the panel side often has serious parasitic effects, and the driving ability of the buffer on the panel side is usually weak, it takes a long time to transmit the signal to the IC side, and it is time consuming to store the signal into a sampling capacitor. Hence, the performance of signal processing and the resolution of the signal are difficult to be improved. There is still a need for solutions to improve the performance of signal processing in the field.

### SUMMARY OF THE INVENTION

An embodiment provides a signal processing circuit including a buffer, a first capacitor, a second capacitor, a first switch and a second switch. The buffer is used to receive an external signal and accordingly generate an input signal, and the buffer includes an input terminal for receiving the external signal, and an output terminal for outputting the input signal. The first switch is coupled to the output terminal of the buffer and the first capacitor. The second switch is coupled to the output terminal of the buffer and the second capacitor. The first switch and the second switch are turned on alternately.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 illustrate a signal processing circuit according to an embodiment.

FIG. 3 is a timing diagram of the operations of the signal processing circuit shown in FIG. 1 and FIG. 2.

FIG. 4 illustrates a signal processing circuit according to another embodiment.

FIG. 5 illustrates a flowchart of a signal processing method for the signal processing circuits in FIG. 1, FIG. 2 and FIG. 4.

FIG. 6 illustrates a signal processing circuit according to another embodiment.

### DETAILED DESCRIPTION

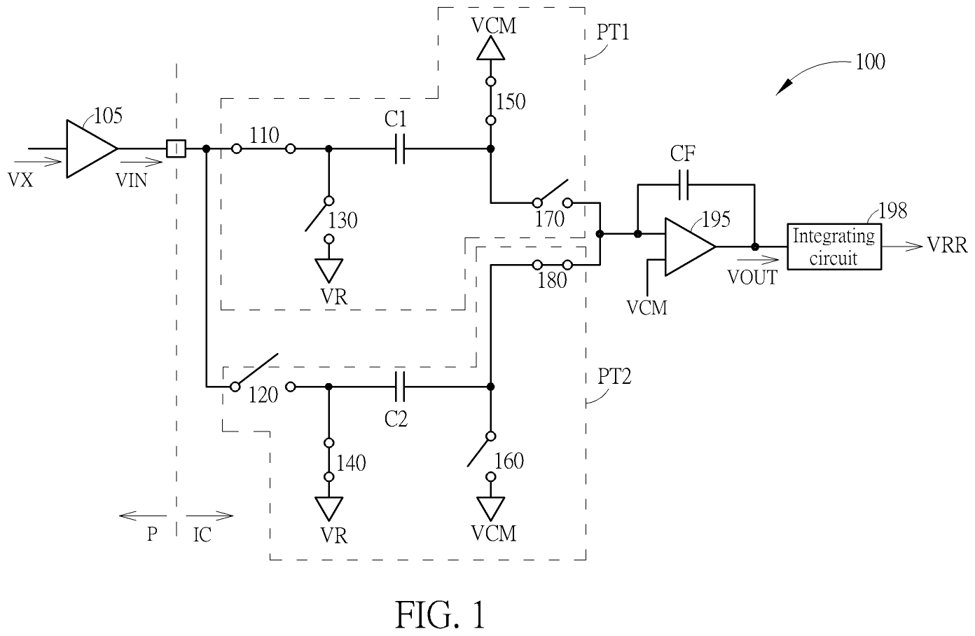

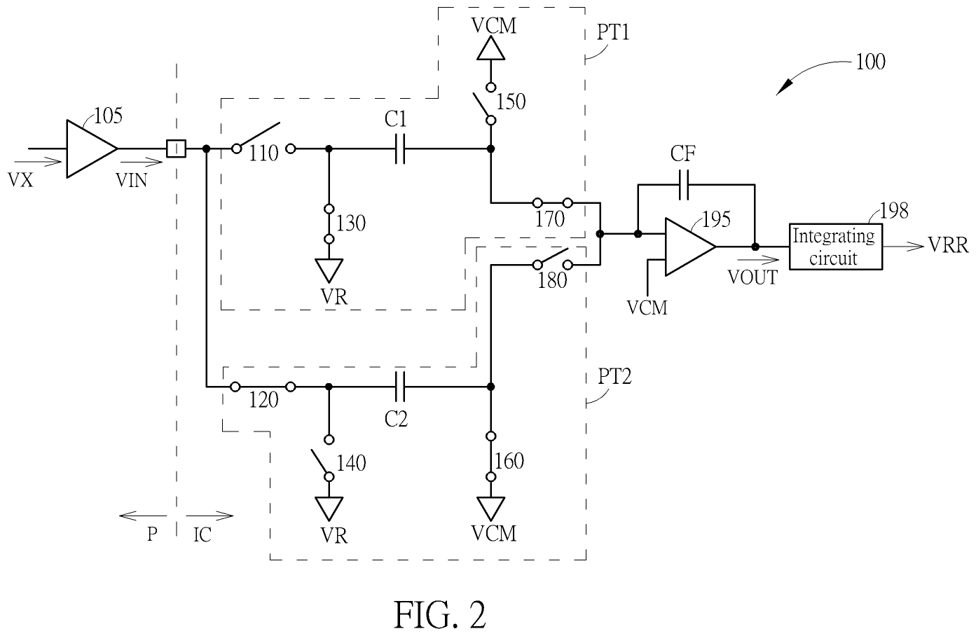

FIG. 1 and FIG. 2 illustrate a signal processing circuit 100 according to an embodiment. The input signal VIN can be sampled through the path unit PT1 as shown in FIG. 1 and be sampled through the path unit PT2 as shown in FIG. 2, related details are described as below. Each of the switches and capacitors in the text can include a first terminal and a second terminal, and related couplings are described as below.

As shown in FIG. 1 and FIG. 2, the signal processing circuit 100 can include a buffer 105 and path units PT1 and PT2. The path unit PT1 can include a first switch 110 and a first capacitor C1, and the path unit PT2 can include a second switch 120 and a second capacitor C2.

The buffer 105 can include an input terminal for receiving an external signal VX, and an output terminal for outputting the input signal VIN.

The first terminals of the first switch 110 and the second switch 120 can be coupled to the output terminal of the buffer 105. The first terminal of the capacitor C1 can be coupled to the second terminal of the first switch 110. The first terminal of the capacitor C2 can be coupled to the second terminal of the second switch 120. The first switch 110 and the second switch 120 can be turned on alternately rather than simultaneously.

As shown in FIG. 1 and FIG. 2, the path unit PT1 can further include a third switch 130, a fifth switch 150 and a seventh switch 170. The path unit PT2 can further include a fourth switch 140, a sixth switch 160 and an eighth switch 180.

The third switch 130 can include a first terminal coupled to the second terminal of the first switch 110, and a second terminal coupled to a reference voltage terminal VR. The fourth switch 140 can include a first terminal coupled to the second terminal of the second switch 120, and a second terminal coupled to the reference voltage terminal VR. The fifth switch 150 can include a first terminal coupled to an operating voltage terminal VCM, and a second terminal coupled to the second terminal of the first capacitor C1. The sixth switch 160 can include a first terminal coupled to the second terminal of the second capacitor C2, and a second terminal coupled to the operating voltage terminal VCM. The seventh switch 170 can include a first terminal coupled to the second terminal of the first capacitor C1, and a second terminal. The eighth switch 180 can include a first terminal coupled to the second terminal of the second capacitor C2, and a second terminal coupled to the second terminal of the seventh switch 170.

As shown in FIG. 1, when the first switch 110 is turned on, the fourth switch 140, the fifth switch 150 and the eighth switch 180 can be turned on, and the third switch 130, the sixth switch 160 and the seventh switch 170 can be turned off.

In FIG. 2, when the second switch 120 is turned on, the fourth switch 140, the fifth switch 150 and the eighth switch 180 can be turned off, and the third switch 130, the sixth switch 160 and the seventh switch 170 can be turned on.

In another embodiment, the signal processing circuit 100 can further include an amplifier 195, a feedback capacitor CF and an integrating circuit 198.

The amplifier 195 can include a first input terminal coupled to the second terminal of the seventh switch 170, a second input terminal coupled to the operating voltage terminal VCM, and an output terminal for outputting an output signal VOUT. The output signal VOUT can be corresponding to the input signal VIN.

The feedback capacitor CF can include a first terminal coupled to the first input terminal of the amplifier 195, and a second terminal coupled to the output terminal of the amplifier 195.

The integrating circuit 198 can perform an integrating operation to generate a result signal VRR according to the output signal VOUT.

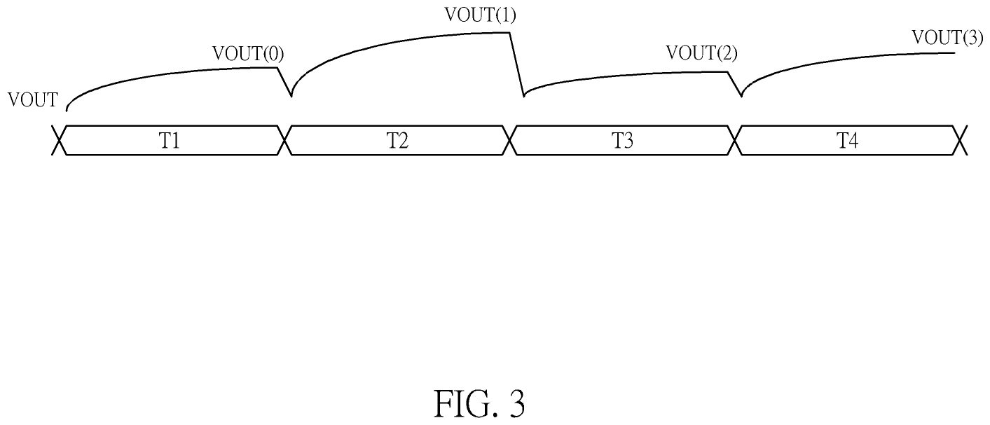

FIG. 3 is a timing diagram of the operations of the signal processing circuit 100 shown in FIG. 1 and FIG. 2. In FIG. 3, the output signal VOUT corresponding to the first period T1, the second period T2 and the third period T3 can be respectively denoted as VOUT(1), VOUT(2) and VOUT(3). The output signal VOUT corresponding to a period preceding the first period T1 (referred to as the zeroth period below) can be denoted as VOUT(0). As shown in FIG. 1, FIG. 2 and FIG. 3, the operations of the signal processing circuit 100 can be as below.

During the first period T1, the states of the switches of the signal processing circuit 100 can be as shown in FIG. 1. The first switch 110 can be turned on, the second switch 120 can be turned off, and the input signal VIN can be transmitted to the first capacitor C1 to be gradually stored into the first capacitor C1.

During the first period T1, the first capacitor C1 can sample the input signal VIN, and the amplifier 195 can generate the output signal VOUT(0) corresponding to the period preceding the first period T1 (i.e. the zeroth period). The signal sampled and stored by the second capacitor C2 during the zeroth period can be transmitted to the amplifier 195 through the eighth switch 180 as shown in FIG. 3, and the signal level of the output signal VOUT(0) can rise accordingly. During the first period T1, the integrating circuit 198 can use the output signal VOUT(0) to perform the integrating operation.

During the second period T2 following the first period T1, the states of the switches of the signal processing circuit 100 can be as shown in FIG. 2. The first switch 110 can be turned off, the second switch 120 can be turned on, and the input signal VIN can be transmitted to the second capacitor C2 to be gradually stored into the second capacitor C2.

During the second period T2, the second capacitor C2 can sample the input signal VIN, the signal sampled and stored by the first capacitor C1 during the first period T1 can be transmitted to the amplifier 195 through the seventh switch 170, and the amplifier 195 can generate the output signal VOUT(1) corresponding to the first period T1. The integrating circuit 198 can use the output signal VOUT(1) to perform the integrating operation.

The operations during the third period T3 following the second period T2 can be similar to the operations during the first period T1. During the third period T3, as shown in FIG. 1 and FIG. 3, the first switch 110 can be turned on, the second switch 120 can be turned off, and the input signal VIN can be sampled through the first switch 110 and the first capacitor C1. The amplifier 195 can generate the output signal VOUT(2) corresponding to the second period T2, and the integrating circuit 198 can use the output signal VOUT(2) to perform the integrating operation.

The operations during the fourth period T4 following the third period T3 can be similar to the operations during the second period T2. During the fourth period T4, as shown in FIG. 2 and FIG. 3, the first switch 110 can be turned off, the second switch 120 can be turned on, and the input signal VIN can be sampled through the second switch 120 and the second capacitor C2. The amplifier 195 can generate the output signal VOUT(3) corresponding to the third period T3, and the integrating circuit 198 can use the output signal VOUT(3) to perform the integrating operation.

In other words, a plurality of path units of the signal processing circuit 100 can be used to synchronously perform sampling and integration of the signals, so as to perform pipelined and synchronous signal processing. As shown in FIG. 1 and FIG. 2, when the path unit PT1 is used to sample a signal, the amplifier 195 can generate the output signal VOUT according to another signal sampled through the path unit PT2 during the previous period, and the integrating circuit 198 can perform the integrating operation accordingly. When the path unit PT2 is used to sample a signal, the amplifier 195 can generate the output signal VOUT according to another signal sampled through the path unit PT1 during the previous period, and the integrating circuit 198 can perform the integrating operation accordingly.

As above, when one of the first switch 110 and the second switch 120 is being used to sample the input signal VIN, the output signal VOUT generated through the other one of the first switch 110 and the second switch 120 during the previous period can be used by the integrating circuit 198 for performing the integrating operation. When the integrating circuit 198 is performing the integrating operation, the signals are gradually transmitted from the buffer 105. As a result, the sampling operation and the integrating operation can be synchronously performed.

As shown in FIG. 1 and FIG. 2, the buffer 105 can be disposed at the panel P. The first switch 110 to the eighth switch 180, the first capacitor C1, the second capacitor C2, the feedback capacitor CF, the amplifier 195 and the integrating circuit 198 can be disposed in the integrated circuit IC. The integrated circuit IC can be located outside the panel P.

Generally, the transmission speed of the signal in the panel P is much slower than that in the integrated circuit IC, which is not conducive to signal processing. With the circuit and operations described in FIG. 1 to FIG. 3, the speed of signal processing is increased and the resolution is improved.

In the embodiment of FIG. 1 and FIG. 2, if it takes first operating time for the integrated circuit IC to transmit a piece of data, it takes second operating time for the buffer 105 of the panel P to transmit the same piece of data, and the second operating time is n times the first operating time, the integrating circuit 198 can perform N integrating operations according to the output signals VOUT corresponding to N periods. Here, N is a positive number larger than zero, and N is the largest positive integer not greater than n. It can be expressed as N=floor(n) or N=└n┘.

The data collected with a single sampling in prior art can be obtained with N samplings in this embodiment. The noises obtained in a plurality of samplings can be reduced by one another during the integrating process, so the signal-to-noise ratio (SNR) is improved, and the resolution of the output signal VOUT can be equivalently improved to be N^{1/2} times.

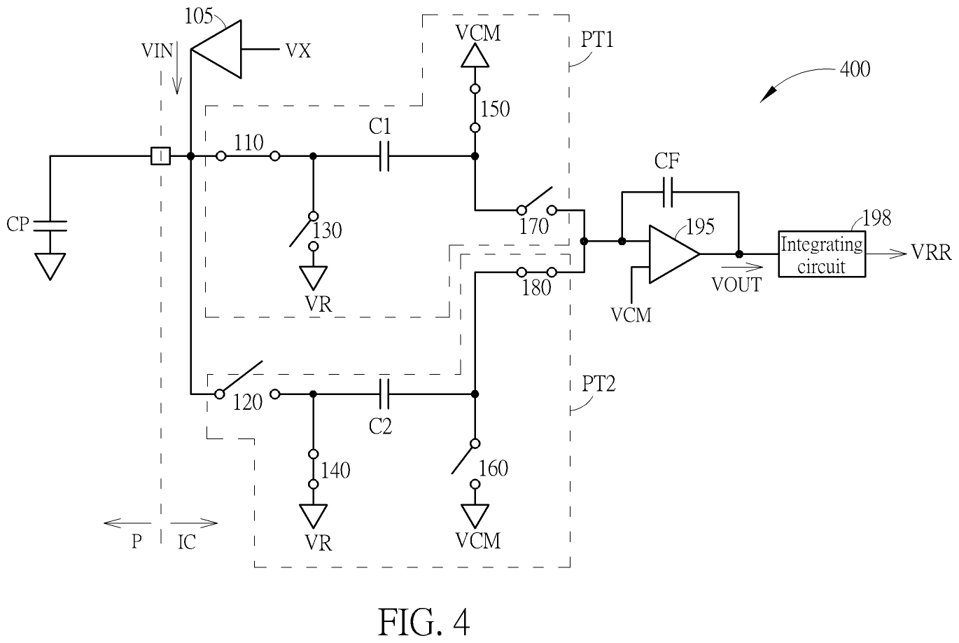

FIG. 4 illustrates a signal processing circuit 400 according to another embodiment. The signal processing circuit 400 can be similar to the signal processing circuit 100 in FIG. 1 and FIG. 2. However, in the signal processing circuit 400, the output terminal of the buffer 105 can be coupled to the panel P, and the buffer 105, the first switch 110 to the eighth switch 180, the first capacitor C1, the second capacitor C2, the feedback capacitor CF, the amplifier 195 and the integrating circuit 198 can be disposed in the integrated circuit IC. The integrated circuit IC can be located outside the panel P. For example, the signal processing circuit 400 can be used for touch detection.

Similar to FIG. 1, FIG. 4 illustrates the scenario where the first switch 110 is turned on. In another scenario, the switches in FIG. 4 can be operated as shown in FIG. 2, and the operations are not repeatedly described.

In FIG. 4, the capacitor CP can represent the load of the panel P. Generally, since the load of the panel P is larger, the signal transmission through the buffer 105 is slowed down. By using the signal processing circuit 400, when the signal is being sampled, the panel P will gradually enter a stable state, and the output signal VOUT of the previous period can be used for the integrating operation. Hence, the speed of signal processing and the resolution are both improved.

The switches shown in FIG. 1, FIG. 2 and FIG. 4 can be transistor switches. For an N-type transistor switch, a high voltage can be applied to the control terminal to turn on the switch. For a P-type transistor switch, a low voltage can be applied to the control terminal to turn on the switch.

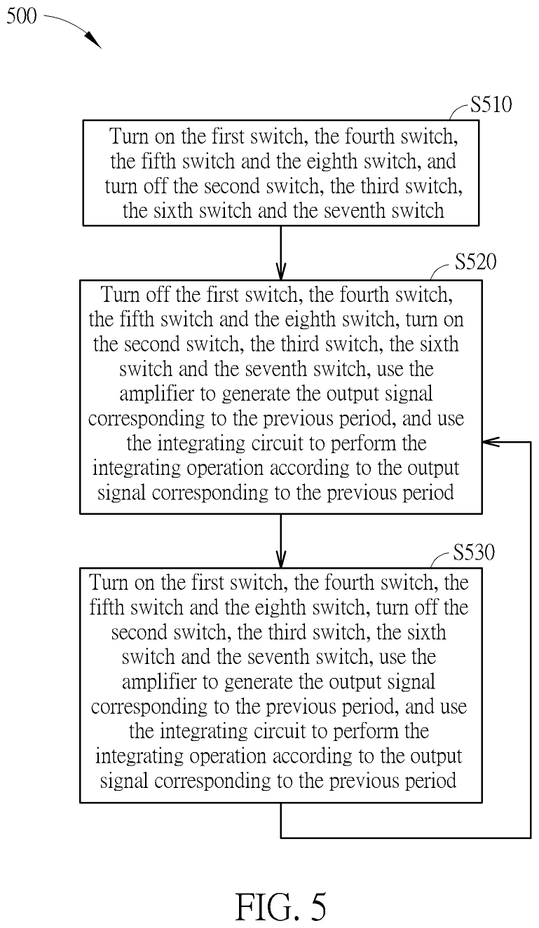

FIG. 5 illustrates a flowchart of a signal processing method 500 for the signal processing circuits 100 and 400 in FIG. 1, FIG. 2 and FIG. 4. The signal processing method 500 can include the following steps.

Step 510: turn on the first switch 110, the fourth switch 140, the fifth switch 150 and the eighth switch 180, and turn off the second switch 120, the third switch 130, the sixth switch 160 and the seventh switch 170;

Step 520: turn off the first switch 110, the fourth switch 140, the fifth switch 150 and the eighth switch 180, turn on the second switch 120, the third switch 130, the sixth switch 160 and the seventh switch 170, use the amplifier 195 to generate the output signal VOUT corresponding to the previous period, and use the integrating circuit 198 to perform the integrating operation according to the output signal VOUT corresponding to the previous period; and

Step 530: turn on the first switch 110, the fourth switch 140, the fifth switch 150 and the eighth switch 180, turn off the second switch 120, the third switch 130, the sixth switch 160 and the seventh switch 170, use the amplifier 195 to generate the output signal VOUT corresponding to the previous period, and use the integrating circuit 198 to perform the integrating operation according to the output signal VOUT corresponding to the previous period.

For example, Step S510 can be an initial step and be corresponding to FIG. 1. Step S520 can be corresponding to FIG. 2 and the second period T2 and the fourth period T4 in FIG. 3. Step S530 can be corresponding to FIG. 1 and the first period T1 and the third period T3 in FIG. 3.

Steps S520 and S530 can be performed repeatedly, so as to control the switches of the path units PT1 and PT2 in turn. The relevant principles and effects can be as above, and will not be repeated.

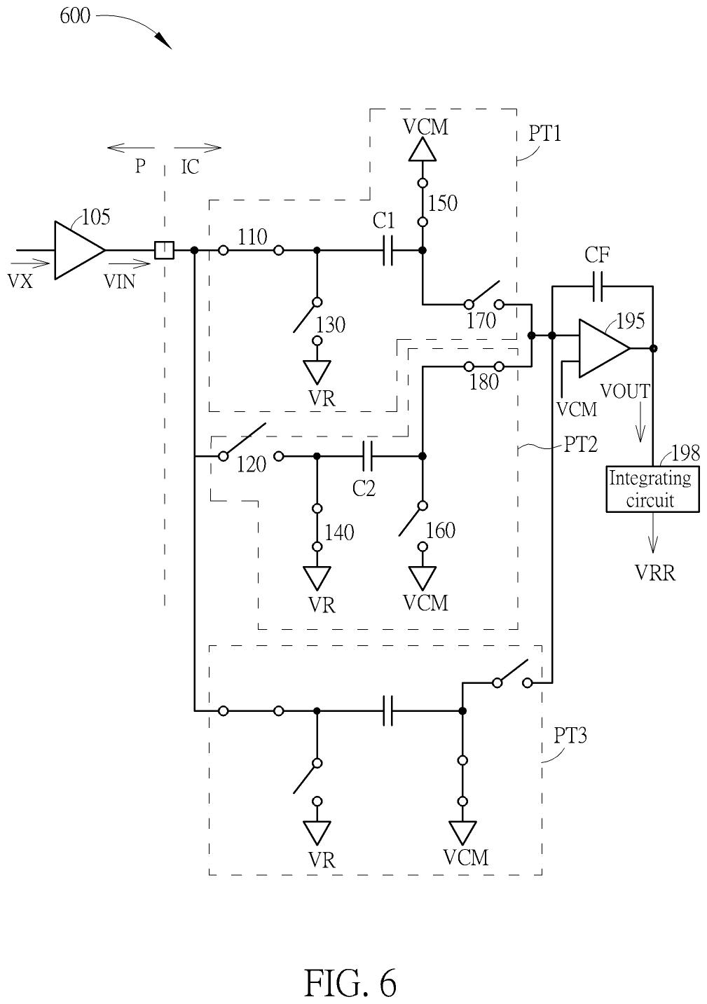

FIG. 6 illustrates a signal processing circuit 600 according to another embodiment. The signal processing circuit 600 can be similar to the signal processing circuit 100, and the signal processing circuit 600 further includes a path unit PT3. In FIG. 6, when signals are being sampled through the path units PT1 and PT3, the integrating circuit 198 can synchronously perform an integrating operation according to a signal sampled previously. Hence, the speed of signal processing and the resolution are improved. Related details will not be repeated.

In summary, by means of the signal processing circuits 100, 400 and 600, and signal processing method 500, an input signal can be sampled, and an output signal generated previously can be used to perform an integrating operation synchronously. Problems caused by the difference of the signal transmission speeds of the panel P and the integrated circuit IC are reduced, and the resolution of the signal is improved.

Those skilled in the art will readily observe that numerous modifications and alterations of the device and method may be made while retaining the teachings of the invention. Accordingly, the above disclosure should be construed as limited only by the metes and bounds of the appended claims.

1: A signal processing circuit, comprising:
a buffer configured to receive an external signal and accordingly generate an input signal, the buffer comprising an input terminal configured to receive the external signal, and an output terminal configured to output the input signal;
a first capacitor;
a second capacitor;
a first switch coupled to the output terminal of the buffer and the first capacitor; and
a second switch coupled to the output terminal of the buffer and the second capacitor;
wherein the first switch and the second switch are turned on alternately.

2: The signal processing circuit of claim 1, further comprising:
a third switch coupled to the first switch and a reference voltage terminal;
a fourth switch coupled to the second switch and the reference voltage terminal;
a fifth switch coupled to the first capacitor and an operating voltage terminal;
a sixth switch coupled to the second capacitor and the operating voltage terminal;
a seventh switch coupled to the first capacitor and the fifth switch; and
an eighth switch coupled to the second capacitor and the seventh switch.

3: The signal processing circuit of claim 2, wherein:
when the first switch is turned on, the fourth switch, the fifth switch and the eighth switch are turned on, and the third switch, the sixth switch and the seventh switch are turned off.

4: The signal processing circuit of claim 2, wherein:
when the second switch is turned on, the fourth switch, the fifth switch and the eighth switch are turned off, and the third switch, the sixth switch and the seventh switch are turned on.

5: The signal processing circuit of claim 2, further comprising:
an amplifier comprising a first input terminal coupled to the seventh switch and the eighth switch, a second input terminal coupled to the operating voltage terminal, and an output terminal configured to output an output signal; and
a feedback capacitor coupled to the first input terminal and the output terminal of the amplifier;
wherein the output signal is corresponding to the input signal.

6: The signal processing circuit of claim 5, further comprising:
an integrating circuit coupled to the amplifier, and configured to perform an integrating operation to generate a result signal according to the output signal.

7: The signal processing circuit of claim 1, wherein:
the buffer is disposed at a panel;
the first switch, the second switch, the first capacitor and the second capacitor are disposed at an integrated circuit; and
the integrated circuit is located outside the panel.

8: The signal processing circuit of claim 1, wherein the output terminal of the buffer is coupled to a panel;
the buffer, the first switch, the second switch, the first capacitor and the second capacitor are disposed at an integrated circuit; and
the integrated circuit is located outside the panel.

9: The signal processing circuit of claim 5, further comprising:
an integrating circuit coupled to the amplifier, and configured to perform N integrating operations according to output signals during N respective periods;
wherein the buffer is disposed at a panel;
the first switch, the second switch, the third switch, the fourth switch, the fifth switch, the sixth switch, the seventh switch, the eighth switch, the first capacitor, the second capacitor, the amplifier and the integrating circuit are disposed at an integrated circuit outside the panel;
the integrated circuit requires a first operation time to transmit a piece of data, the buffer requires a second operation time to transmit the piece of data, the second operation time is n times the first operation time, n>0, and N is a largest positive integer not greater than n.
